(19) United States
(12) Patent Application Publication
(10) Pub. No.: US 2026/0255606 A1
(43) Pub. Date: Aug. 27, 2026

(54) MEMORY DEVICE AND FABRICATION METHOD THEREOF

(71) Applicant: Winbond Electronics Corp., Taichung City (TW)

(72) Inventor: Frederick Chen, Tainan (TW)

(73) Assignee: Winbond Electronics Corp., Taichung City (TW)

(21) Appl. No.: 19/061,945

(22) Filed: Feb. 24, 2025

(51) Int. Cl. H10B 43/30; H10B 43/27

(52) U.S. Cl. CPC H10B 43/30; H10B 43/27

(57) ABSTRACT

A memory device includes a first source line, a first drain line, a charge storage layer, a first word line and a first channel layer. The charge storage layer is laterally disposed between the first word line and the first channel layer. The first word line and the first channel layer extend along a second direction perpendicular to the first direction. The first source line and the first drain line pass through the first channel layer. The first channel layer laterally surrounds the first source line and the first drain line. The first source line and the first drain line extend along a first direction.

### BACKGROUND

### Technical Field

The present invention relates to a memory device and a fabrication method thereof. In particular, the present invention relates to fabrication method of a NOR memory device.

### Description of Related Art

Flash memory is widely used in personal computers and electronic devices due to its advantages of allowing multiple cycles of data storage, reading, and erasing, as well as the ability to retain data even after power is lost. NOR flash memory is a commonly used type of flash memory in the industry. The design of NOR flash memory provides fast random access, making it particularly suitable for code storage and execution. With advancements in technology, electronic products are increasingly moving toward faster, more efficient, and more compact designs. To reduce the size of semiconductor devices without compromising memory performance, many manufacturers are actively developing new memory structures. Currently, high-density and high-integration three-dimensional (3D) memory structures are receiving growing attention as a key direction for advancing memory technology.

### SUMMARY

According to some embodiments of the present invention, a memory device includes a first source line, a first drain line, a charge storage layer, a first word line and a first channel layer. The first source line and the first drain line extend along a first direction. The first word line and the first channel layer extend along a second direction perpendicular to the first direction. The first source line and the first drain line pass through the first channel layer, and the first channel layer laterally surrounds the first source line and the first drain line. The charge storage layer is laterally disposed between the first word line and the first channel layer.

According to some embodiments of the present invention, a fabrication method of a memory device includes the following steps. A first channel layer, a second channel layer, and a spacer structure are formed, wherein the first channel layer and the second channel layer are arranged along a first direction and are separated from each other by the spacer structure. A sidewall of the first channel layer and a sidewall of the second channel layer are etched to form a first recess and a second recess. A charge storage layer is formed in the first recess and the second recess. A first conductive material layer is formed on the charge storage layer. The first conductive material layer is etched to form a first word line and a second word line, wherein the charge storage layer is laterally disposed between the first word line and the first channel layer and laterally disposed between the second word line and the second channel layer. A plurality of first openings penetrating though the first channel layer and the second channel layer are formed. A first source line and a first drain line are formed in the plurality of first openings, wherein the first source line and the first drain line extend along the first direction, and the first channel layer and the second channel layer laterally surround the first source line and the first drain line.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1C illustrate various perspective views of a memory device in accordance with some embodiments of the present disclosure.

FIG. 2A to FIG. 17C illustrate various perspective views of a fabrication method of a memory device in accordance with some embodiments of the present disclosure.

FIG. 18 illustrates a perspective view of a memory device in accordance with some embodiments of the present disclosure.

### DESCRIPTION OF THE EMBODIMENTS

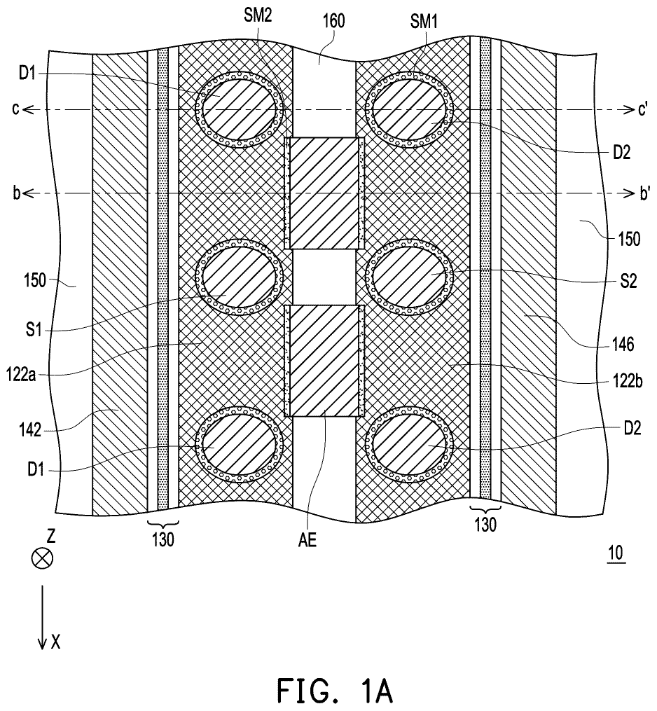

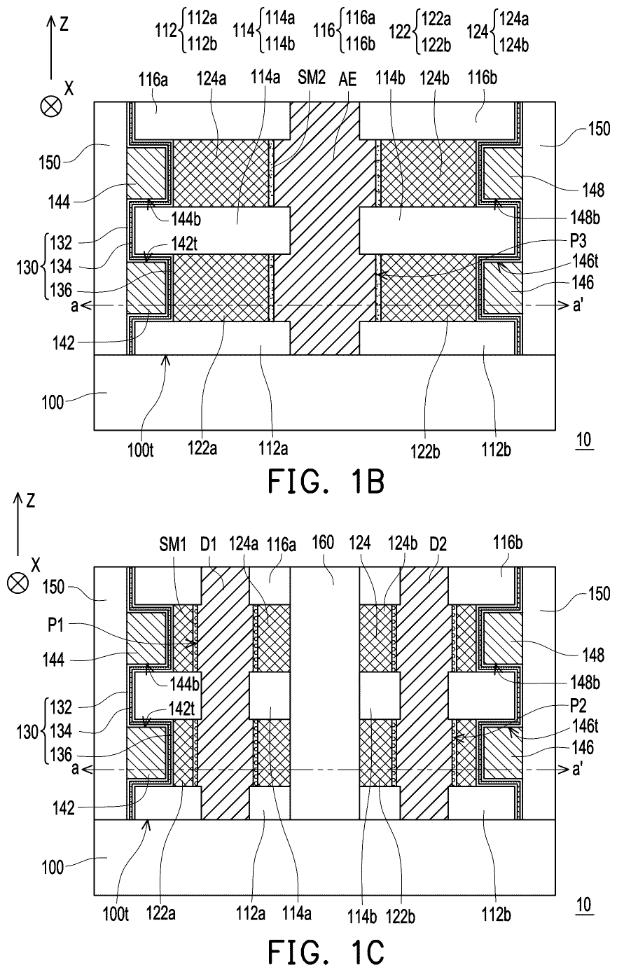

FIG. 1A presents a top-down perspective view of the memory device 10. FIGS. 1B and 1C provide vertical cross-sectional views of the memory device 10, corresponding to the positions along lines b-b′ and c-c′ in FIG. 1A, respectively. The view in FIG. 1A aligns with the position of line a-a′ in FIGS. 1B and 1C. Referring to FIG. 1A to FIG. 1C, a memory device 10 includes one or more first source lines S1, one or more first drain lines D1, a charge storage layer 130, a first word line 142 and a first channel layer 122. In this embodiment, the memory device 10 further includes a first spacer structure 112, a second spacer structure 114, a third spacer structure 116, a second channel layer 124, one or more second source lines S2, one or more second drain lines D2, a dielectric structure 150, an isolation structure 160, a first semiconductor layer SM1, a second semiconductor layer SM2 and one or more auxiliary electrodes AE.

The first spacer structure 112, the first channel layer 122, the second spacer structure 114, the second channel layer 124 and the third spacer structure 116 are sequentially stacked along a first direction Z and located above the substrate 100. The first channel layer 122 is separated from the second channel layer 124 by the second spacer structure 114. The first spacer structure 112, the first channel layer 122, the second spacer structure 114, the second channel layer 124 and the third spacer structure 116 extend along a second direction X, which is perpendicular to the first direction Z. In some embodiments, the first direction Z is perpendicular to a top surface 100t of the substrate 100, and the second direction X is parallel to the top surface 100t of the substrate 100.

In some embodiments, the first spacer structure 112, the second spacer structure 114, and the third spacer structure 116 are composed of dielectric materials, such as silicon oxide, silicon nitride, silicon oxynitride, aluminum oxide, hafnium oxide, or combinations of the aforementioned materials, or other suitable dielectric materials. The first channel layer 122 and the second channel layer 124 are composed of silicon or other suitable semiconductor materials. In some embodiments, the first channel layer 122 and the second channel layer 124 are silicon layers formed by epitaxy. Compared to polysilicon, these epitaxial silicon layers may reduce electron scattering issues and provide better conductance.

In some embodiments, the first channel layer 122 and the second channel layer 124 may be referred to as nanosheets. For example, the thickness of each of the first channel layer 122 and the second channel layer 124 ranges from 5 nm to 100 nm.

The isolation structure 160 is located above the substrate 100 and extends continuously from the first spacer structure 112 through the first channel layer 122, the second spacer structure 114, and the second channel layer 124, reaching the third spacer structure 116. The isolation structure 160 is laterally disposed between the first portion 112a and the second portion 112b of the first spacer structure 112, between the first portion 122a and the second portion 122b of the first channel layer 122, between the first portion 114a and the second portion 114b of the second spacer structure 114, between the first portion 124a and the second portion 124b of the second channel layer 124, and between the first portion 116a and the second portion 116b of the third spacer structure 116.

In some embodiments, the isolation structure 160 is composed of dielectric materials, such as silicon oxide, silicon nitride, silicon oxynitride, aluminum oxide, hafnium oxide, or combinations of the aforementioned materials, or other suitable dielectric materials.

The first source line S1, the first drain line D1, the second source line S2, and the second drain line D2 are located above the substrate 100. The first source line S1, the first drain line D1, the second source line S2, and the second drain line D2 extend along the first direction Z and extend from the first channel layer 122 to the second channel layer 124. The first source line S1, the first drain line D1, the second source line S2, and the second drain line D2 pass through the first spacer structure 112, the first channel layer 122, the second spacer structure 114, the second channel layer 124 and the third spacer structure 116. Each of the first spacer structure 112, the first channel layer 122, the second spacer structure 114, the second channel layer 124 and the third spacer structure 116 laterally surrounds the first source line S1, the first drain line D1, the second source line S2 and the second drain line D2.

In this embodiment, the isolation structure 160 is laterally positioned between the first source line S1 and the second source line S2, and between the first drain line D1 and the second drain line D2. The first source line S1 and the first drain line D1 pass through the first portion 112a of the first spacer structure 112, the first portion 122a of the first channel layer 122, the first portion 114a of the second spacer structure 114, the first portion 124a of the second channel layer 124, and the first portion 116a of the third spacer structure 116. In the other hand, the second source line S2 and the second drain line D2 pass through the second portion 112b of the first spacer structure 112, the second portion 122b of the first channel layer 122, the second portion 114b of the second spacer structure 114, the second portion 124b of the second channel layer 124, and the second portion 116b of the third spacer structure 116.

The auxiliary electrode AE is located above the substrate 100 and embedded in the isolation structure 160. The auxiliary electrode AE extends along the first direction Z and pass through the first spacer structure 122, the first channel layer 122, the second spacer structure 114, the second channel layer 124, and the third spacer structure 116. The auxiliary electrode AE is laterally disposed between the first portion 112a and the second portion 112b of the first spacer structure 112, between the first portion 122a and the second portion 122b of the first channel layer 122, between the first portion 114a and the second portion 114b of the second spacer structure 114, between the first portion 124a and the second portion 124b of the second channel layer 124, and between the first portion 116a and the second portion 116b of the third spacer structure 116.

In some embodiments, the first source line S1, the first drain line D1, the second source line S2, the second drain line D2 and the auxiliary electrode AE are composed of metals such as copper, tungsten, aluminum, gold, silver, or alloys of one or more of these metals, or a combination of at least two of these metals. In other embodiments, the first source line S1, the first drain line D1, the second source line S2, the second drain line D2 and the auxiliary electrode AE may include other conductive materials, such as metal oxides or metal nitrides.

In some embodiments, sidewalls of the first source line S1 and the first drain line D1 have first protruding structures P1 extending towards the first channel layer 122 and the second channel layer 124. In some embodiments, sidewalls of the second source line S2 and the second drain line D2 have second protruding structures P2 extending towards the first channel layer 122 and the second channel layer 124. In some embodiments, a sidewall of the auxiliary electrode AE has third protruding structures P3 extending towards the first channel layer 122 and the second channel layer 124.

The first semiconductor layer SM1 is disposed on sidewalls of the first source line S1, the first drain line D1, the second source line S2, and the second drain line D2. The first semiconductor layer SM1 is located between the first source line S1 and the first channel layer 122, between the first drain line D1 and the first channel layer 122, between the first source line S1 and the second channel layer 124, between the first drain line D1 and the second channel layer 124, between the second source line S2 and the first channel layer 122, between the second drain line D2 and the first channel layer 122, between the second source line S2 and the second channel layer 124, and between the second drain line D2 and the second channel layer 124.

The second semiconductor layer SM2 is disposed on sidewalls of the auxiliary electrode AE. The second semiconductor layer SM2 is located between the auxiliary electrode AE and the first channel layer 122 and between the auxiliary electrode AE and the second channel layer 124.

The first semiconductor layer SM1 and the second semiconductor layer SM2 have different doping types. For example, both of the first semiconductor layer SM1 and the second semiconductor layer SM2 are doped silicon semiconductors, with one being n-type doped and the other being p-type doped. In some embodiments, the first semiconductor layer SM1 is n-type doped, while the second semiconductor layer SM2 is p-type doped. Additionally, in some embodiments, the first channel layer 122 and the second channel layer 124 are also p-type semiconductors; however, their doping concentration is lower than that of the second semiconductor layer SM2.

In some embodiments, the arrangement of the first semiconductor layer SM1 facilitates the formation of ohmic contacts between the source line and the channel layer, as well as between the drain line and the channel layer. Similarly, the configuration of the second semiconductor layer SM2 allows for the formation of an ohmic contact between the auxiliary electrode AE and the channel layer.

The first word line 142, the second word line 144, the third word line 146 and the fourth word line 148 are located above the substrate 100 and extend along the second direction X. In some embodiments, the first word line 142, the second word line 144, the third word line 146, and the fourth word line 148 are composed of metals such as copper, tungsten, aluminum, gold, silver, or alloys of one or more of these metals, or a combination of at least two of these metals. In other embodiments, the first word line 142, the second word line 144, the third word line 146, and the fourth word line 148 may include other conductive materials, such as metal oxides or metal nitrides.

The first channel layer 122 is laterally located between the auxiliary electrode AE and the first word line 142 and laterally between the auxiliary electrode AE and the third word line 146. The second channel layer 124 is laterally located between the auxiliary electrode AE and the second word line 144 and laterally between the auxiliary electrode AE and the fourth word line 148. The auxiliary electrode AE is used to apply a bias or ground voltage to the first channel layer 122 and the second channel layer 124, thereby preventing floating body potential in the channel layers.

The charge storage layer 130 is laterally disposed between the first word line 142 and the first channel layer 122, between the second word line 144 and the second channel layer 124, between the third word line 146 and the first channel layer 122, and between the fourth word line 148 and the second channel layer 124. The charge storage layer 130 extends from between the first word line 142 and the first channel layer 122 to between the second word line 144 and the second channel layer 124 and extends from between the third word line 146 and the first channel layer 122 to between the fourth word line 148 and the second channel layer 124.

In some embodiments, the charge storage layer 130 is vertically disposed between the second spacer structure 114 and a top surface 142t of the first word line 142 and vertically disposed between the second spacer structure 114 and a bottom surface 144b of the second word line 144. Similarly, the charge storage layer 130 is vertically disposed between the second spacer structure 114 and a top surface 146t of the third word line 146 and vertically disposed between the second spacer structure 114 and a bottom surface 148b of the fourth word line 148.

The charge storage layer 130 is, for example, an oxide/nitride/oxide (ONO) composite layer. That is, the charge storage layer 130 includes a blocking oxide layer 132, a charge storage layer 134 and a tunnel oxide layer 136.

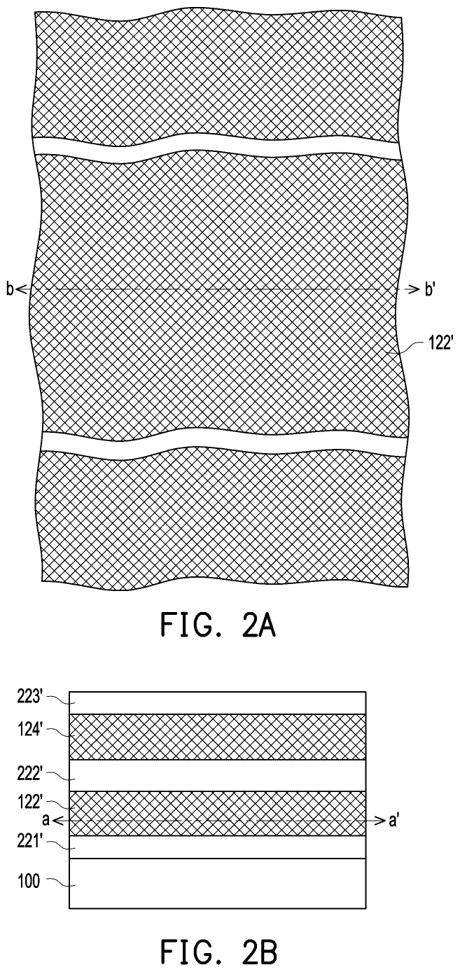

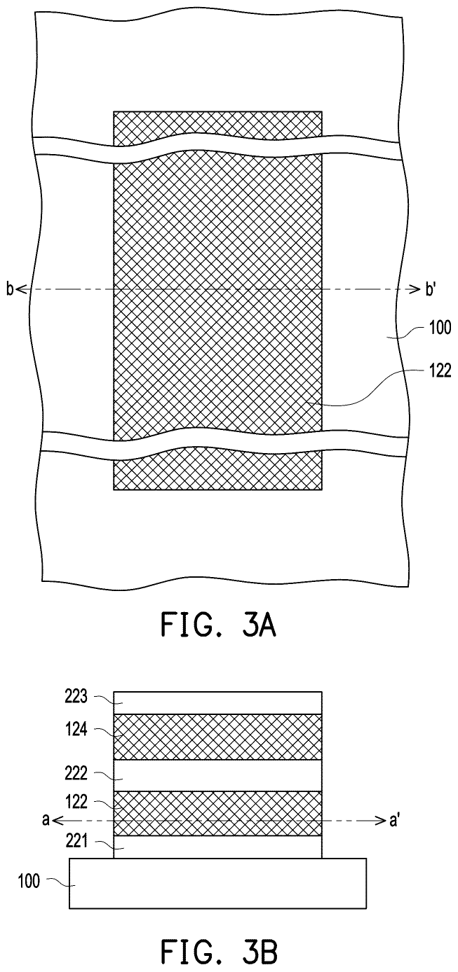

FIGS. 2A to 17C illustrate various perspective views of the fabrication method for the memory device 10 shown in FIGS. 1A to 1C. In FIGS. 2A to 17C, the figures labeled with “A” present top-down perspective views of the workpiece at various stages during the fabrication process of the memory device along lines a-a′, while the figures labeled with “B” and “C” correspond to vertical cross-sectional views along lines b-b′ and c-c′, respectively.

Referring to FIG. 2A and FIG. 2B, a first sacrificial layer 221′, a first semiconductor material layer 122′, a second sacrificial layer 222′, a second semiconductor material layer 124′, and a third sacrificial layer 223′ are sequentially formed above the substrate 100, potentially by epitaxy. In some embodiments, the materials of the first, second, and third sacrificial layers 221′, 222′, and 223′ differ from those of the first and second semiconductor material layers 122′ and 124′. For example, the first, second, and third sacrificial layers 221′, 222′, and 223′ may be composed of silicon-germanium, while the first and second semiconductor material layers 122′ and 124′ are composed of silicon.

Referring to FIGS. 3A and 3B, the stack structure consisting of the first sacrificial layer 221′, the first semiconductor material layer 122′, the second sacrificial layer 222′, the second semiconductor material layer 124′, and the third sacrificial layer 223′ is patterned (e.g., by wet or dry etching) to form a semiconductor stack consisting of a patterned first sacrificial layer 221, the first channel layer 122, a patterned second sacrificial layer 222, the second channel layer 124, and a patterned third sacrificial layer 223 exposing the underlying layers. In FIG. 3B, the stack structure is patterned to expose the substrate 100; however, the disclosure is not limited thereto. In other embodiments, additional structures (not shown in the figures) may be present between the stack structure and the substrate 100, and the patterning process would expose these intermediate structures. In some embodiments, the patterning process removes portions of the stack structure corresponding to the locations where the word lines will later be formed.

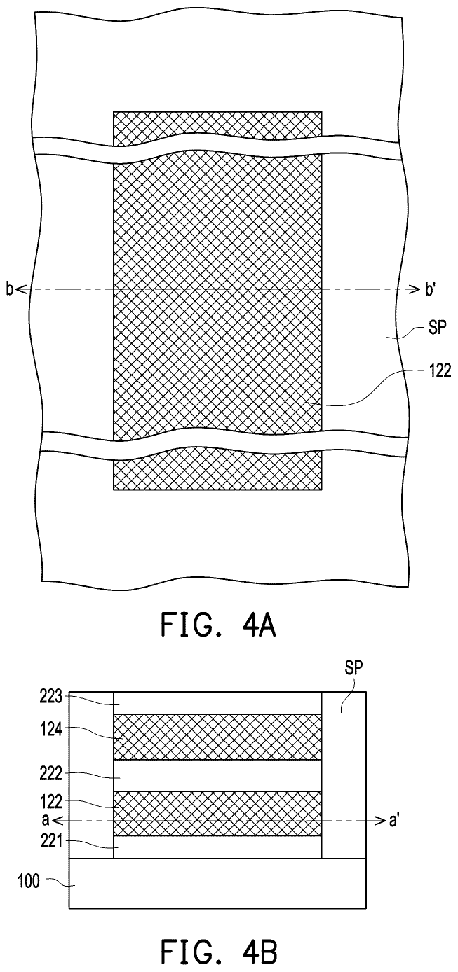

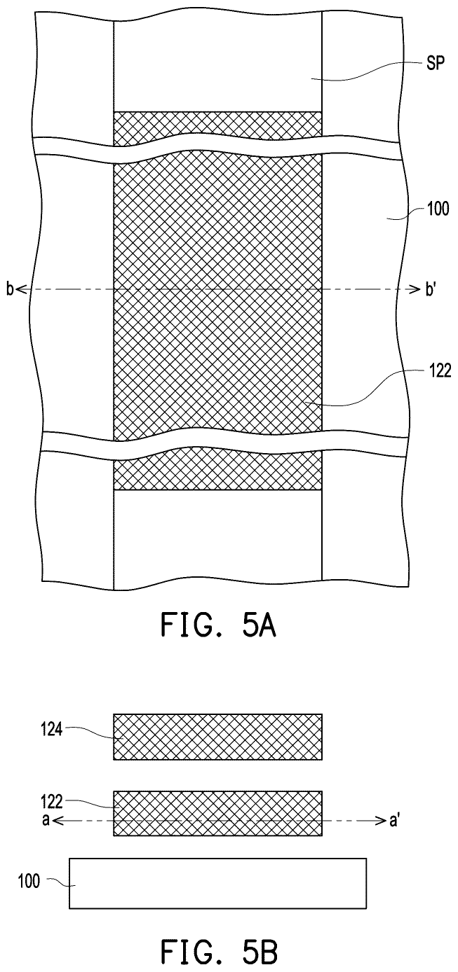

Referring to FIGS. 4A and 4B, a support structure SP is formed around and in contact with the patterned first sacrificial layer 221, the first channel layer 122, the patterned second sacrificial layer 222, the second channel layer 124 and the patterned third sacrificial layer 223. In some embodiments, the support structure SP is composed of an oxide (such as silicon oxide) or other insulating materials.

Referring to FIGS. 5A and 5B, the support structure SP is patterned to expose sidewalls the patterned first sacrificial layer 221, the first channel layer 122, the patterned second sacrificial layer 222, the second channel layer 124, and the patterned third sacrificial layer 223. In some embodiments, the patterning process removes portions of the support structure SP corresponding to the locations where the word lines will later be formed.

The patterned first sacrificial layer 221, the patterned second sacrificial layer 222, and the third patterned sacrificial layer 223 are removed using a wet etching process. During this process, the support structure SP provides support to the first channel layer 122 and the second channel layer 124, preventing the structure from collapsing.

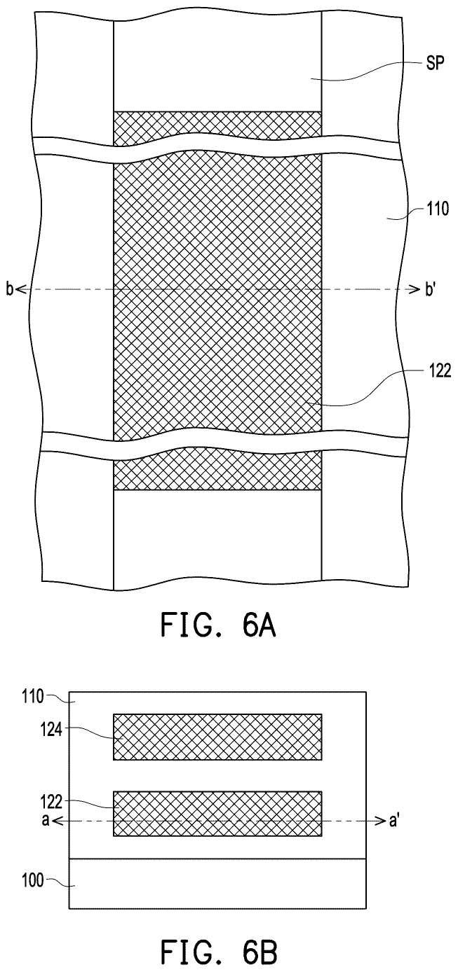

Referring to FIGS. 6A and 6B, a dielectric spacer layer 110 is formed around the first channel layer 122 and the second channel layer 124, filling the space between them. This enhances the insulation between the first channel layer 122 and the second channel layer 124. In some embodiments, the dielectric spacer layer 110 is composed of an oxide (such as silicon oxide) or other insulating materials.

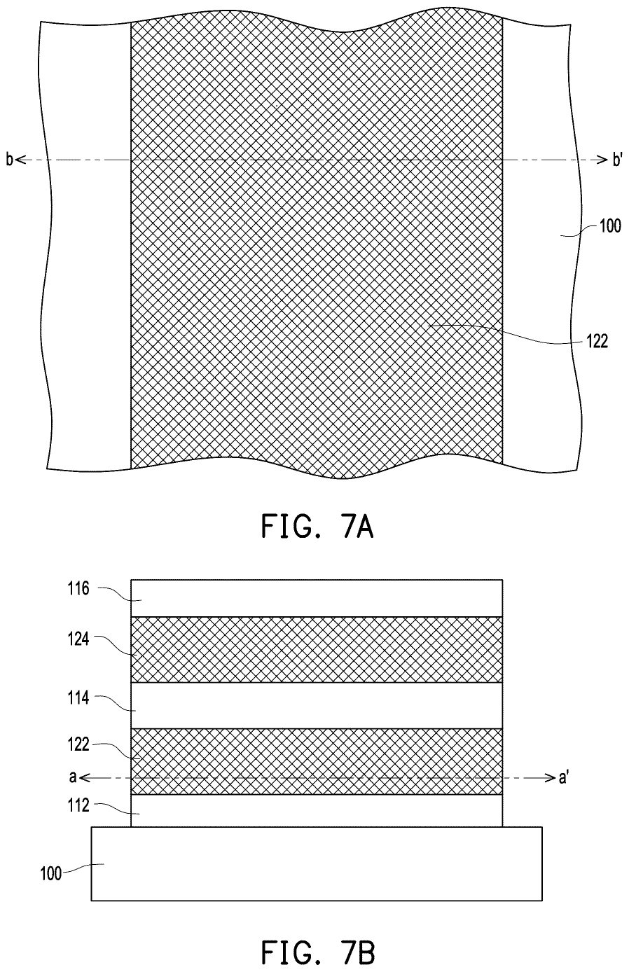

Referring to FIGS. 7A and 7B, the dielectric spacer layer 110 is patterned (e.g., by wet or dry etching) to expose sidewalls of the first channel layer 122 and the second channel layer 124. In some embodiments, the patterning process removes portions of the dielectric spacer layer 110 corresponding to the locations where the word lines will later be formed. The dielectric spacer layer 110 is patterned to form the first spacer structure 112, the second spacer structure 114 and the third spacer structure 116.

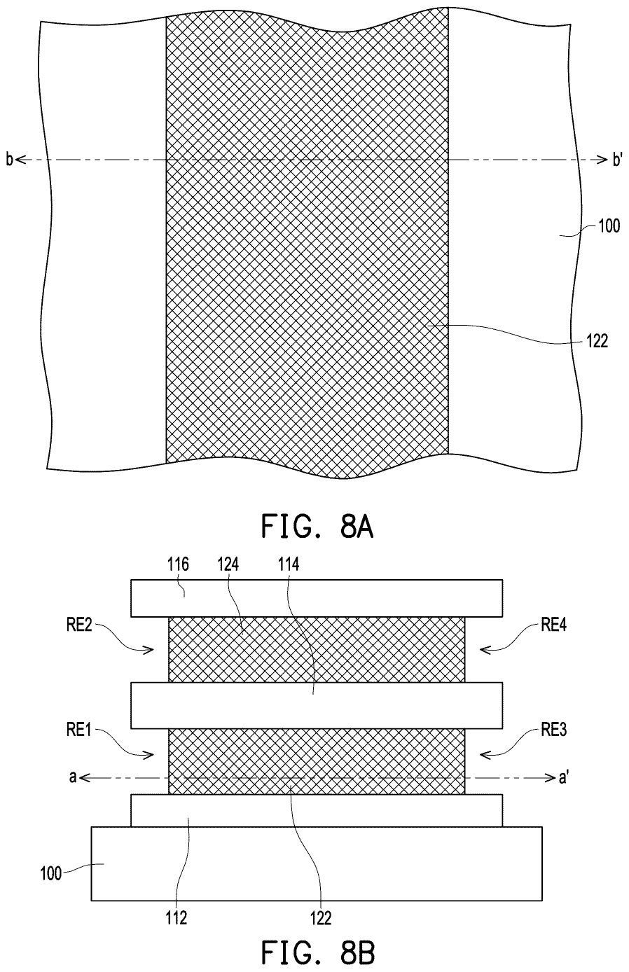

Referring to FIGS. 8A and 8B, the sidewalls of the first channel layer 122 and the second channel layer 124 are etched to form a first recess RE1, a second recess RE2, a third recess RE3, and a fourth recess RE4. Specifically, a wet etching process is used to etch the first channel layer 122 relative to the first spacer structure 112 and the second spacer structure 114, creating the first recess RE1 and the third recess RE3. Similarly, the second channel layer 124 is etched relative to the second spacer structure 114 and the third spacer structure 116 to form the second recess RE2 and the fourth recess RE4.

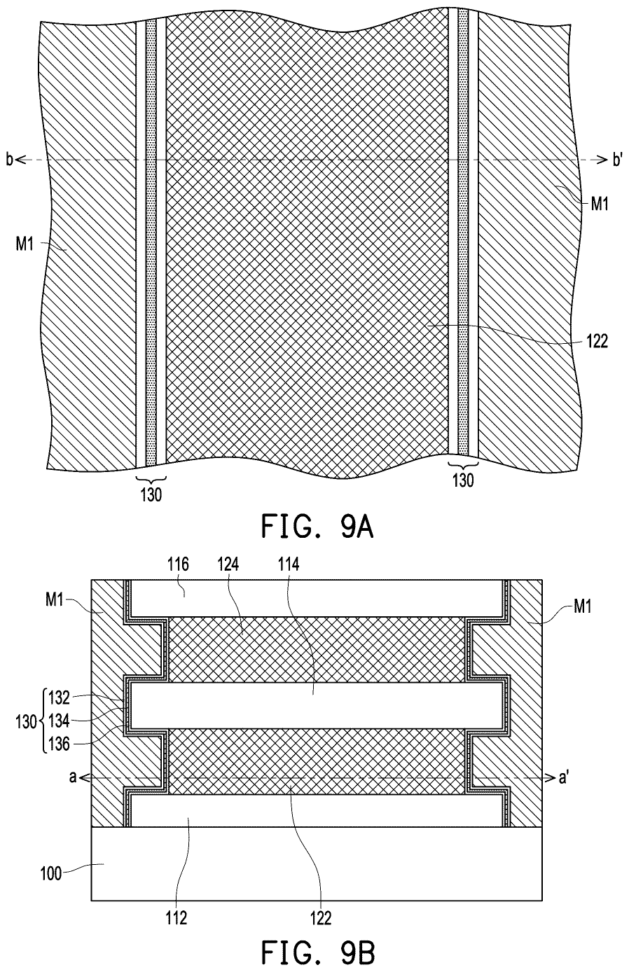

Referring to FIGS. 9A and 9B, the charge storage layer 130 is formed in the first recess RE1, the second recess RE2, the third recess RE3, and the fourth recess RE4. A first conductive material layer M1 is formed on the charge storage layer 130.

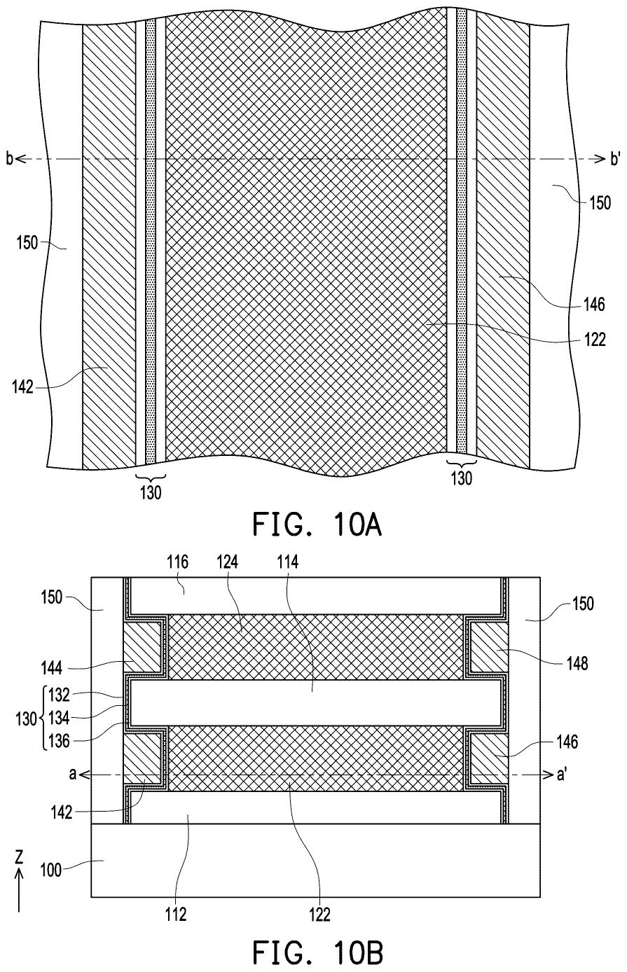

Referring to FIGS. 10A and 10B, the first conductive material layer M1 is etched to form the first word line 142, the second word line 144, the third word line 146 and the fourth word line 148. The first word line 142 and the third word line 146 overlap with the second word line 144 and the fourth word line 148 in the first direction Z. The first word line 142 and the third word line 146 are separated from the second word line 144 and the fourth word line 148 by the second spacer structure 114.

The dielectric structure 150 fills the spaces left by the removal of the first conductive material layer M1, thereby covering the first word line 142, the second word line 144, the third word line 146, and the fourth word line 148 with both the dielectric structure 150 and the charge storage layer 130. In some embodiments, the dielectric structure 150 is composed of an oxide (such as silicon oxide) or other insulating materials.

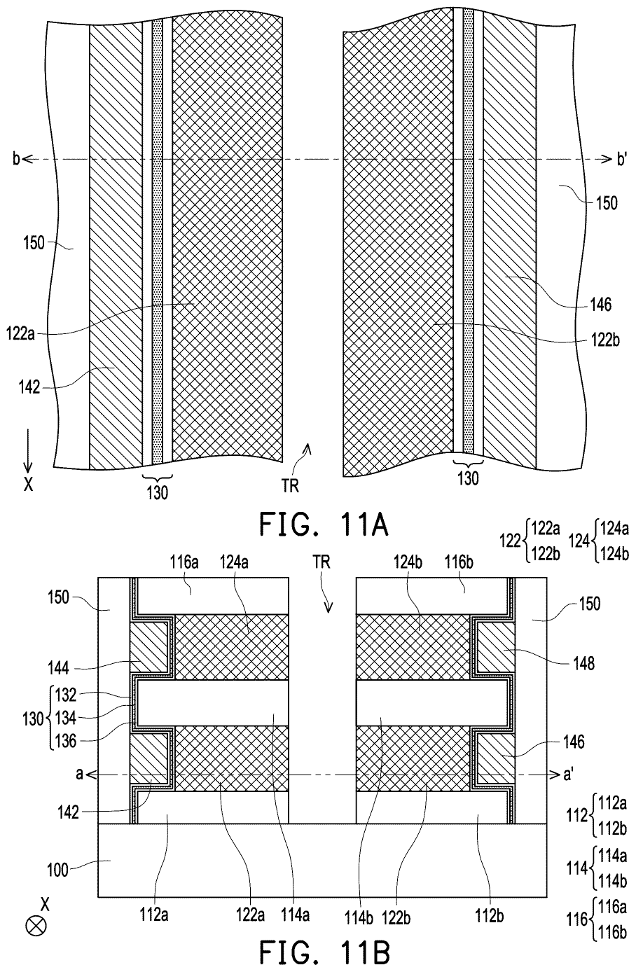

Referring to FIGS. 11A and 11B, an isolation trench TR is formed through the first spacer structure 112, the first channel layer 122, the second spacer structure 114, the second channel layer 124 and the third spacer structure 116. The first spacer structure 112, the first channel layer 122, the second spacer structure 114, the second channel layer 124, the third spacer structure 116 and the isolation trench TR extend along the second direction X.

The isolation trench TR is laterally disposed between the first portion 112a and the second portion 112b of the first spacer structure 112, between the first portion 122a and the second portion 122b of the first channel layer 122, between the first portion 114a and the second portion 114b of the second spacer structure 114, between the first portion 124a and the second portion 124b of the second channel layer 124, and between the first portion 116a and the second portion 116b of the third spacer structure 116.

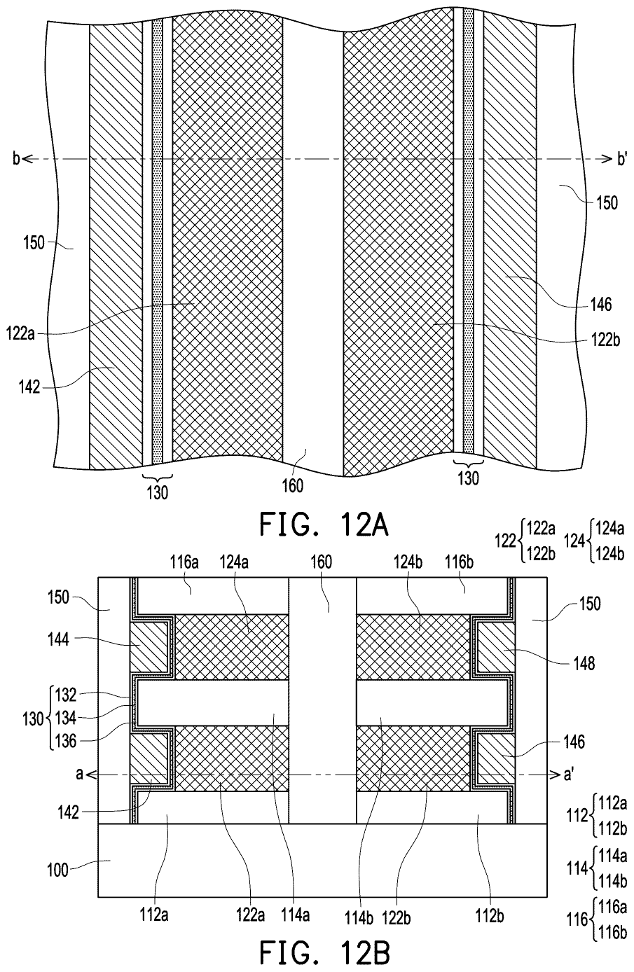

Referring to FIGS. 12A and 12B, the isolation structure 160 is formed in the isolation trench TR.

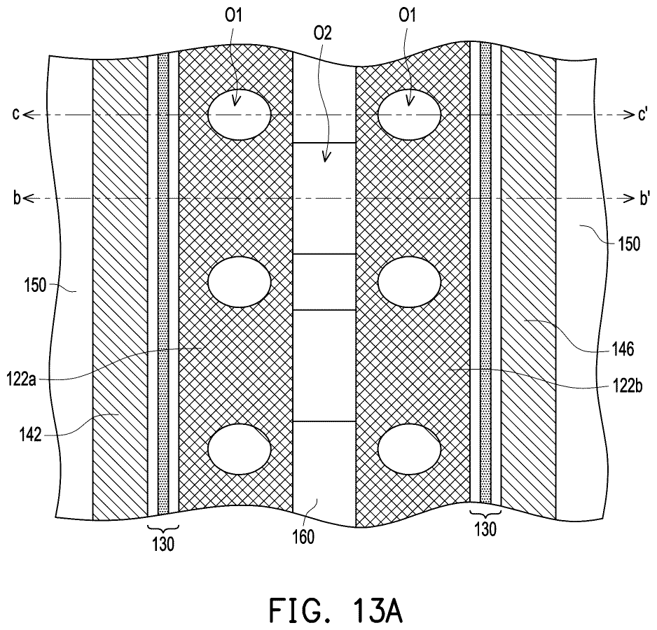

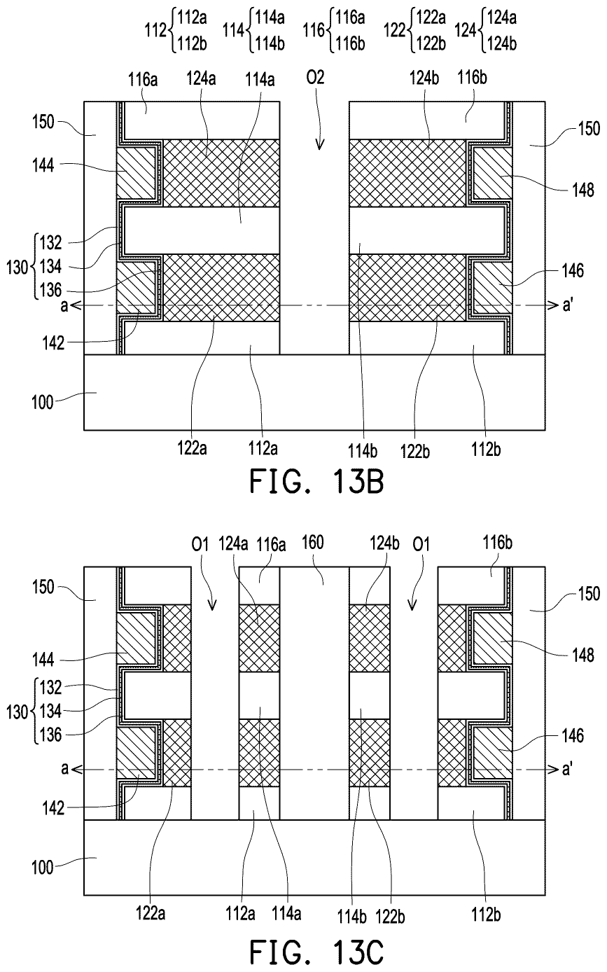

Referring to FIGS. 13A to 13C, first openings O1 are formed though the first spacer structure 112, the first channel layer 122, the second spacer structure 114, the second channel layer 124, and the third spacer structure 116. The first openings O1 may be formed by one or more etching process.

Second openings O2 are formed though the isolation structure 160 to expose the first channel layer 122 and the second channel layer 124.

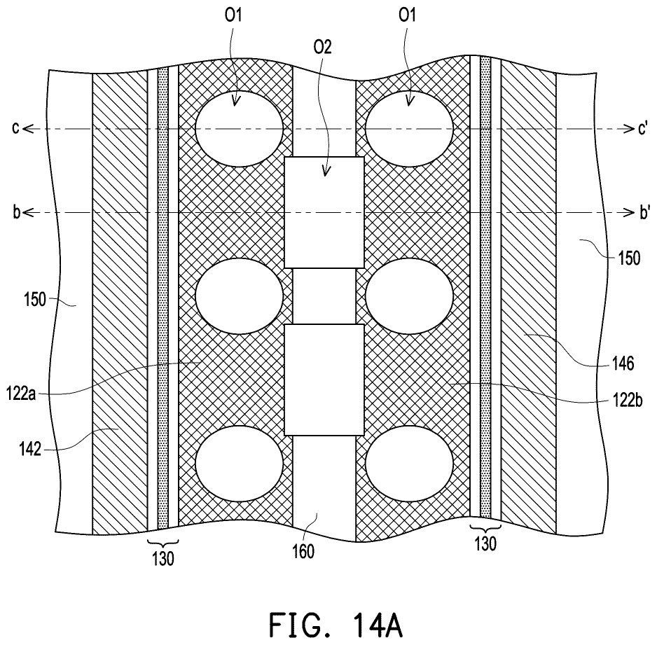

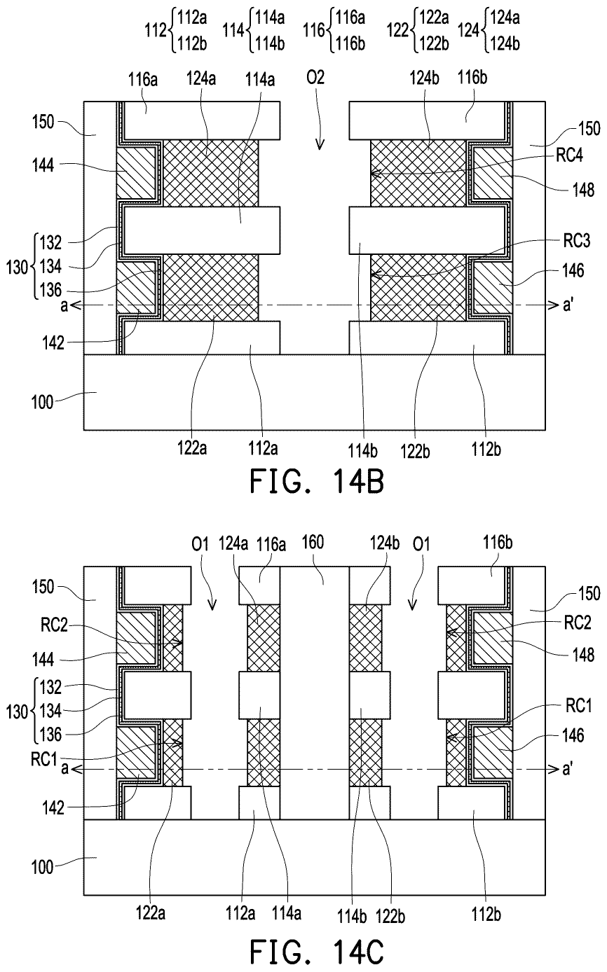

Referring to FIGS. 14A to 14C, the sidewalls of the first channel layer 122 and the second channel layer 124 are etched through the first openings O1. This results in the width of the first openings O1 being greater at the positions corresponding to the first channel layer 122 and the second channel layer 124 than at the positions corresponding to the first spacer structure 112, the second spacer structure 114, and the third spacer structure 116. Each sidewall of the first openings O1 features a recess RC1 extending towards the first channel layer 122 and a recess RC2 extending towards the second channel layer 124.

In other hand, the sidewalls of the first channel layer 122 and the second channel layer are etched through the second openings O2. This results in the width of the second openings O2 being greater at the positions corresponding to the first channel layer 122 and the second channel layer 124 than at the positions corresponding to the first spacer structure 112, the second spacer structure 114, and the third spacer structure 116. Each sidewall of the second openings O2 features a recess RC3 extending towards the first channel layer 122 and a recess RC4 extending towards the second channel layer 124.

In some embodiments, the etching processes performed in the first openings O1 and the second openings O2 may be carried out simultaneously or separately.

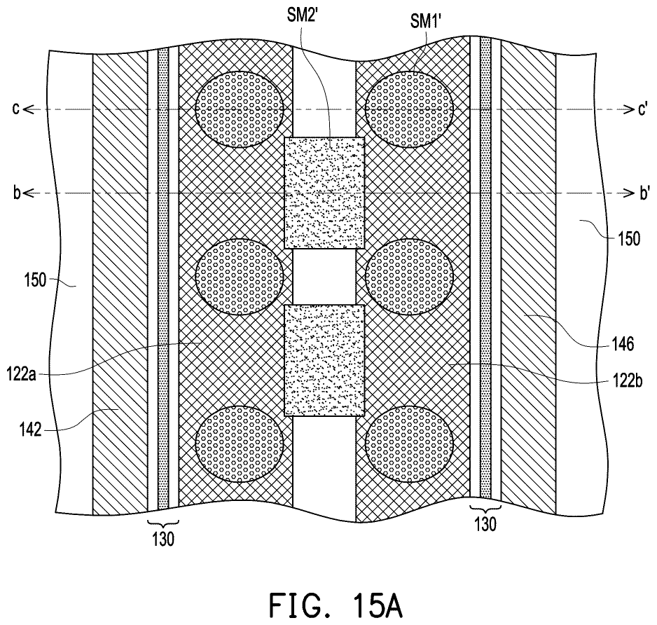

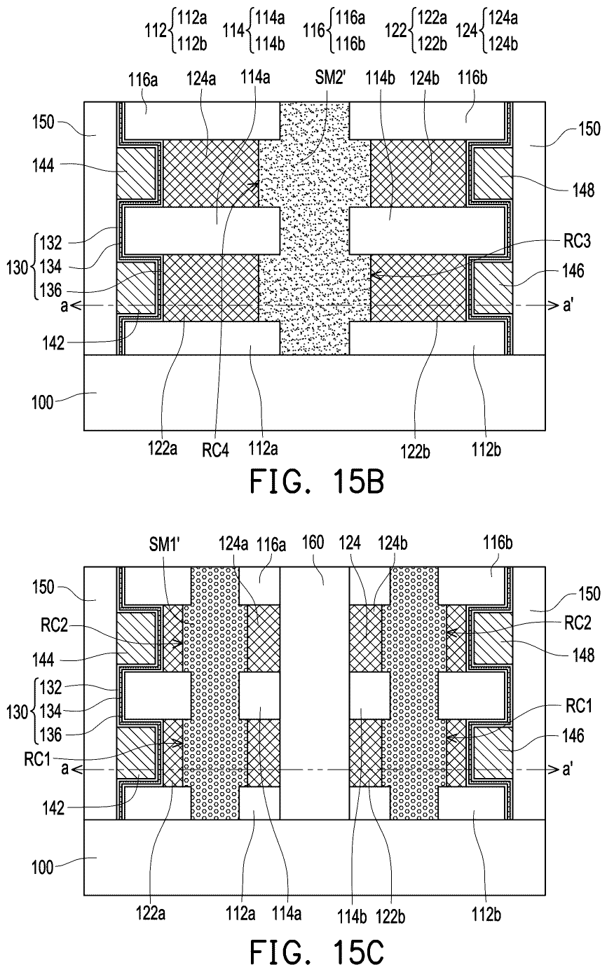

Referring to FIGS. 15A to 15C, a first semiconductor material SM1′ is formed in the first openings O1, and a second semiconductor material SM2′ is formed in the second openings O2. The first semiconductor material SM1′ and the second semiconductor material SM2′ have different doping types.

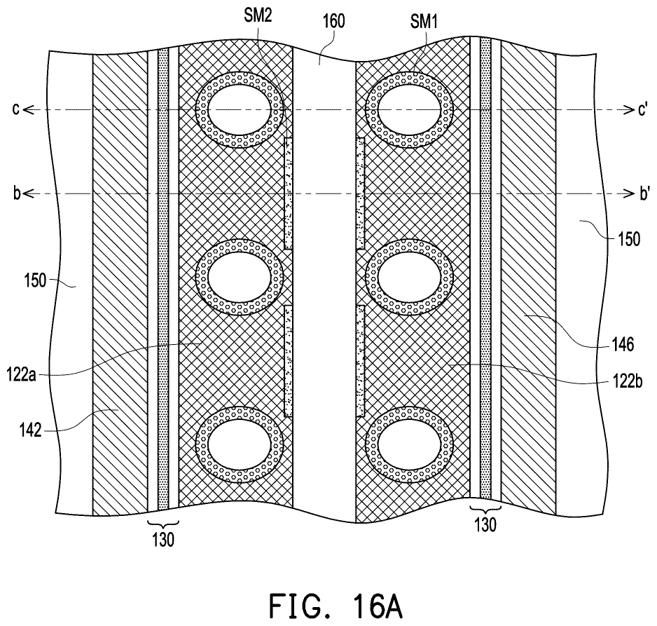

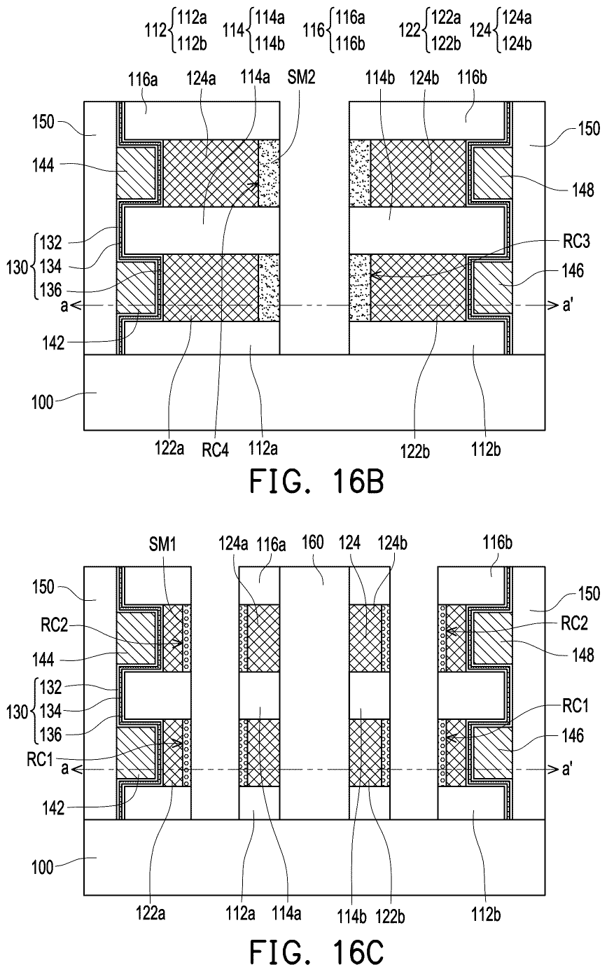

Referring to FIGS. 16A to 16C, etch (e.g., dry etching) the first semiconductor material SM1′ and the second semiconductor material SM2′ so that the remaining portions of the first semiconductor material SM1′ and the second semiconductor material SM2′ are roughly aligned with the first spacer structure 112, the second spacer structure 114, and the third spacer structure 116. In other words, the remaining first semiconductor material SM1′ (i.e. the first semiconductor layer SM1) substantially fills the recesses RC1 and RC2 on the sidewalls of the first openings O1, while the remaining second semiconductor material SM2′ (i.e. the second semiconductor layer SM2) substantially fills the recesses RC3 and RC4 on the sidewalls of the second openings O2.

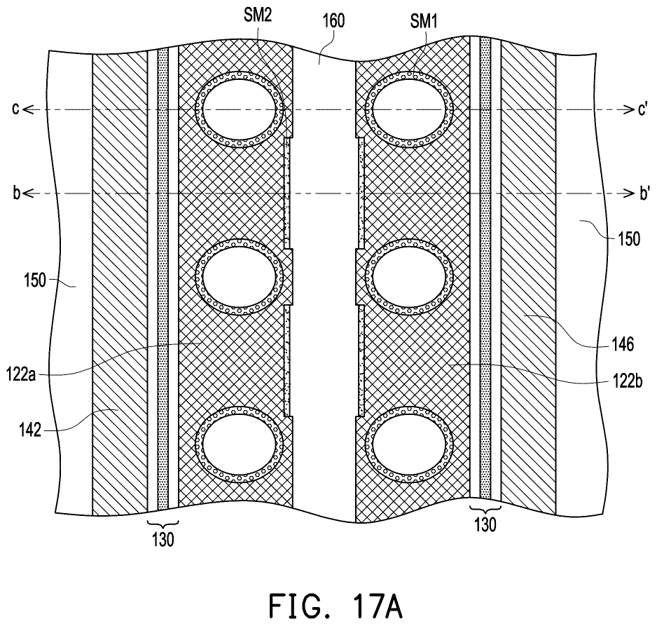

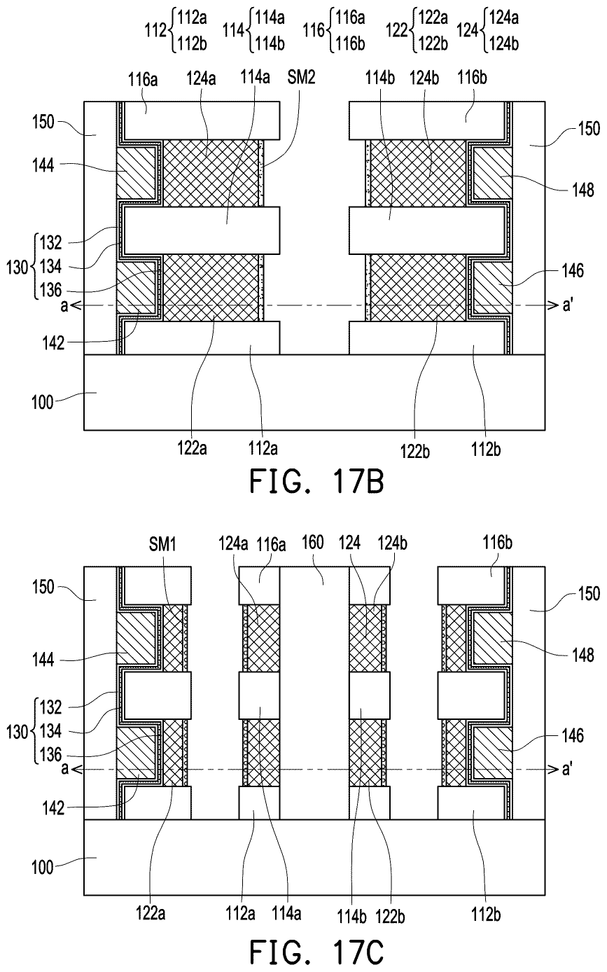

Referring to FIG. 17A to FIG. 17C, a recess process is performed to further etch the first semiconductor layer SM1 and the second semiconductor layer SM2, causing them to recess relative to the first spacer structure 112, the second spacer structure 114, and the third spacer structure 116.

In some embodiments, the etching or recess processes involved in forming the first semiconductor layer SM1 and the second semiconductor layer SM2 may be carried out either simultaneously or separately.

Finally, referring back to FIG. 1A to FIG. 1C, the first source line S1, the first drain line D1, the second source line S2, and the second drain line D2 are formed in the first openings O1, while the auxiliary electrodes AE are formed in the second openings O2. The first source line S1, the first drain line D1, the second source line S2, the second drain line D2, and the auxiliary electrodes AE extend along the first direction X. In some embodiments, a conductive material is first deposited into the first openings O1 and the second openings O2. Then, the excess conductive material beyond the first openings O1 and the second openings O2 is removed, leaving the conductive material within the openings to form the first source line S1, the first drain line D1, the second source line S2, the second drain line D2, and the auxiliary electrodes AE.

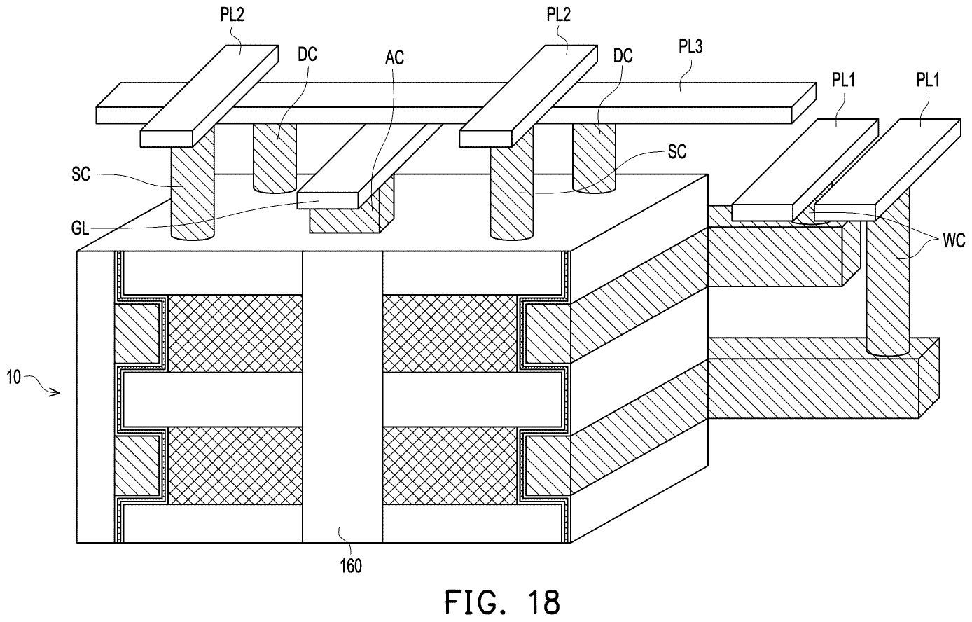

FIG. 18 illustrates a perspective view of the memory device 10 in accordance with some embodiments of the present disclosure. Referring to FIG. 18, the memory device 10 includes multiple first contacts WC, second contacts SC, third contacts DC, and fourth contacts AC. The first contacts WC connect the word lines to the corresponding first pickup lines PL1. The second contacts SC connect the source lines to the corresponding second pickup lines PL2 (also referred to as source lines), while the third contacts DC connect the drain lines to the corresponding third pickup lines PL3 (also referred to as bit lines). The fourth contacts AC connect the auxiliary electrodes to the corresponding signal line GL (such as a ground signal line).

In the memory device 10 of the present invention, the word lines, source lines, and bit lines may be decoded in different directions, facilitating easier decoding while maintaining 3D structure integrity.

In some embodiments, the auxiliary electrodes are connected to the ground signal via an overhead signal line GL, but this disclosure is not limited thereto. In other embodiments, the auxiliary electrodes are electrically connected downward to the substrate, using the substrate for grounding.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a first source line and a first drain line, extending along a first direction;
a first word line and a first channel layer, extending along a second direction perpendicular to the first direction, wherein the first source line and the first drain line pass through the first channel layer, and the first channel layer laterally surrounds the first source line and the first drain line; and
a charge storage layer, laterally disposed between the first word line and the first channel layer.

2. The memory device of claim 1, further comprises:
a substrate, wherein the first word line, the first channel layer, the charge storage layer, the first source line and the first drain line are located above the substrate, wherein the first direction is perpendicular to a top surface of the substrate, and the second direction is parallel to the top surface of the substrate.

3. The memory device of claim 1, further comprises:
a second word line and a second channel layer, extending along the second direction, wherein the charge storage layer extends from between the first word line and the first channel layer to between the second word line and the second channel layer, and wherein the first source line and the first drain line extends from the first channel layer to the second channel layer along the first direction.

4. The memory device of claim 3, further comprises:
a spacer structure, wherein the first channel layer is separated from the second channel layer by the spacer structure.

5. The memory device of claim 1, wherein sidewalls of the first source line and the first drain line have protruding structures extending towards the first channel layer.

6. The memory device of claim 1, further comprises:
an auxiliary electrode, extending along the first direction, wherein the first channel layer is located between the auxiliary electrode and the first word line.

7. The memory device of claim 6, wherein a sidewall of the auxiliary electrode has a protruding structure extending towards the first channel layer.

8. The memory device of claim 6, further comprises:
a first semiconductor layer, located between the first source line and the first channel layer and between the first drain line and the first channel layer; and
a second semiconductor layer, located between the auxiliary electrode and the first channel layer, wherein the first semiconductor layer and the second semiconductor layer are of different doping types.

9. The memory device of claim 6, further comprises:
an isolation structure, laterally disposed between a first portion of the first channel layer and a second portion of the first channel layer, wherein the auxiliary electrode is embedded in the isolation structure.

10. A fabrication method of a memory device, comprising:
forming a first channel layer, a second channel layer, and a spacer structure, wherein the first channel layer and the second channel layer are arranged along a first direction and are separated from each other by the spacer structure;
etching a sidewall of the first channel layer and a sidewall of the second channel layer to form a first recess and a second recess;
forming a charge storage layer in the first recess and the second recess;
forming a first conductive material layer on the charge storage layer;
etching the first conductive material layer to form a first word line and a second word line, wherein the charge storage layer is laterally disposed between the first word line and the first channel layer and laterally disposed between the second word line and the second channel layer;
forming a plurality of first openings penetrating though the first channel layer and the second channel layer; and
forming a first source line and a first drain line in the plurality of first openings, wherein the first source line and the first drain line extend along the first direction, and the first channel layer and the second channel layer laterally surround the first source line and the first drain line.

11. The fabrication method of claim 10, further comprises:
forming an isolation trench in the first channel layer, the second channel layer and the spacer structure, wherein the first channel layer, the second channel layer and the isolation trench extend along a second direction; and
forming an isolation structure in the isolation trench.

12. The fabrication method of claim 11, further comprises:
forming a second opening in the isolation structure and exposing the first channel layer and the second channel layer; and
forming an auxiliary electrode in the second opening, wherein the auxiliary electrode extends along the first direction, and the first channel layer is located between the auxiliary electrode and the first word line.

13. The fabrication method of claim 12, further comprises:
forming a first semiconductor layer in the plurality of first openings before forming the first source line and the first drain line; and
forming a second semiconductor layer in the second opening before forming the auxiliary electrode, wherein the first semiconductor layer and the second semiconductor layer are of different doping types.
